(19) United States
(12) Patent Application Publication
(10) Pub. No.: US 2024/0224625 A1
(43) Pub. Date: Jul. 4, 2024

(54) DISPLAY PANEL AND DISPLAY DEVICE

(71) Applicants: Wuhan Tianma Micro-Electronics Co., Ltd., Wuhan (CN); Wuhan Tianma Microelectronics Co., LTD. Shanghai Branch, Shanghai (CN)

(72) Inventors: Shuyang YU, Wuhan (CN); Xi Chen, Wuhan (CN)

(21) Appl. No.: 18/129,687

(22) Filed: Mar. 31, 2023

(30) Foreign Application Priority Data
Dec. 30, 2022 (CN) 202211724500.0

(51) Int. Cl. H10K 59/126

(52) U.S. Cl. CPC H10K 59/126

(57) ABSTRACT

A display panel and a display device are provided. The display panel includes a substrate, and a first switch transistor disposed on a side of the substrate. The first switch transistor includes a first active layer. The display panel also includes a first light-shielding component disposed on a side of the first active layer away from the substrate. Along a direction perpendicular to a plane where the substrate is located, the first light-shielding component at least partially overlaps with the first active layer. Further, the display panel includes a second light-shielding component. Along a direction parallel to the plane where the substrate is located, the second light-shielding component is disposed on a side of the first active layer.

### CROSS-REFERENCE TO RELATED APPLICATION

This application claims the priority of Chinese patent application No. 202211724500.0, filed on Dec. 30, 2022, the entirety of which is incorporated herein by reference.

### FIELD

The present disclosure generally relates to the field of display technology and, more particularly, relates to a display panel and a display device.

### BACKGROUND

Thin film transistors are often used as the driving elements of an existing display panel. The active layer in the thin film transistor generates photo-carriers after being irradiated by light, which increases the leakage current of the thin film transistor, thereby affecting the display image quality of the display panel. Therefore, how to provide a display panel capable of solving the problem of poor display image quality is an urgent technical problem that needs to be solved.

### SUMMARY

One aspect of the present disclosure provides a display panel. The display panel includes a substrate, and a first switch transistor disposed on a side of the substrate. The first switch transistor includes a first active layer. The display panel also includes a first light-shielding component disposed on a side of the first active layer away from the substrate. Along a direction perpendicular to a plane where the substrate is located, the first light-shielding component at least partially overlaps with the first active layer. Further, the display panel includes a second light-shielding component. Along a direction parallel to the plane where the substrate is located, the second light-shielding component is disposed on a side of the first active layer.

Another aspect of the present disclosure provides a display device. The display device includes a display panel. The display panel includes a substrate, and a first switch transistor disposed on a side of the substrate. The first switch transistor includes a first active layer. The display panel also includes a first light-shielding component disposed on a side of the first active layer away from the substrate. Along a direction perpendicular to a plane where the substrate is located, the first light-shielding component at least partially overlaps with the first active layer. Further, the display panel includes a second light-shielding component. Along a direction parallel to the plane where the substrate is located, the second light-shielding component is disposed on a side of the first active layer.

Other aspects of the present disclosure can be understood by those skilled in the art in light of the description, the claims, and the drawings of the present disclosure.

### BRIEF DESCRIPTION OF THE DRAWINGS

To more clearly illustrate the embodiments of the present disclosure, the drawings will be briefly described below. The drawings in the following description are certain embodiments of the present disclosure, and other drawings may be obtained by a person of ordinary skill in the art in view of the drawings provided without creative efforts.

FIG. 1 illustrates a schematic diagram of an exemplary display panel consistent with disclosed embodiments of the present disclosure;

FIG. 2 illustrates an AA′-sectional view of the display panel in FIG. 1 consistent with disclosed embodiments of the present disclosure;

FIG. 3 illustrates another AA′-sectional view of the display panel in FIG. 1 consistent with disclosed embodiments of the present disclosure;

FIG. 4 illustrates a local zoom-in view of a region C of the display panel in FIG. 1 consistent with disclosed embodiments of the present disclosure;

FIG. 5 illustrates a BB′-sectional view of the region C in FIG. 4 consistent with disclosed embodiments of the present disclosure;

FIG. 6 illustrates another AA′-sectional view of the display panel in FIG. 1 consistent with disclosed embodiments of the present disclosure;

FIG. 7 illustrates a perspective view of a region D in FIG. 4 consistent with disclosed embodiments of the present disclosure;

FIG. 8 illustrates another AA′-sectional view of the display panel in FIG. 1 consistent with disclosed embodiments of the present disclosure;

FIG. 9 illustrates another AA′-sectional view of the display panel in FIG. 1 consistent with disclosed embodiments of the present disclosure;

FIG. 10 illustrates another AA′-sectional view of the display panel in FIG. 1 consistent with disclosed embodiments of the present disclosure;

FIG. 11 illustrates another AA′-sectional view of the display panel in FIG. 1 consistent with disclosed embodiments of the present disclosure; and

FIG. 12 illustrates a schematic diagram of an exemplary display device consistent with disclosed embodiments of the present disclosure.

### DETAILED DESCRIPTION OF THE DISCLOSURE

Reference will now be made in detail to exemplary embodiments of the disclosure, which are illustrated in the accompanying drawings. Wherever possible, the same reference numbers will be used throughout the drawings to refer to the same or the alike parts. The described embodiments are some but not all of the embodiments of the present disclosure. Based on the disclosed embodiments, persons of ordinary skill in the art may derive other embodiments consistent with the present disclosure, all of which are within the scope of the present disclosure.

Similar reference numbers and letters represent similar terms in the following Figures, such that once an item is defined in one Figure, it does not need to be further discussed in subsequent Figures.

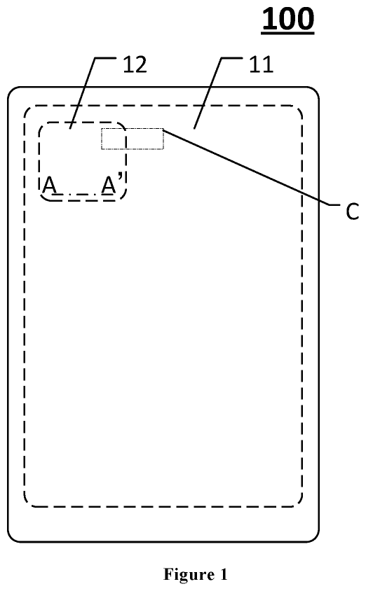

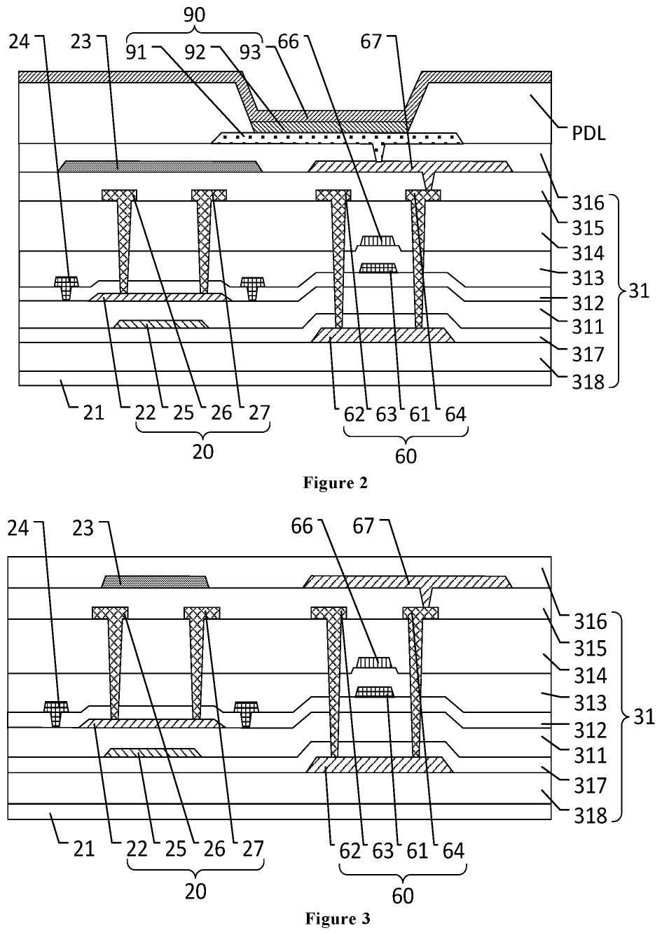

The present disclosure provides a display panel and a display device, to improve the display effect of the display panel. FIG. 1 illustrates a schematic diagram of a display panel consistent with disclosed embodiments of the present disclosure, FIG. 2 illustrates an AA′-sectional view of the display panel in FIG. 1, and FIG. 3 illustrates another AA′-sectional view of the display panel in FIG. 1. Referring to FIGS. 1-3, a display panel 100 may include a substrate 21 and a first switch transistor 20 disposed on a side of the substrate 21. The first switch transistor 20 may include a first active layer 22. The display panel may also include a first light-shielding component 23 disposed on a side of the first active layer 22 away from the substrate 21, and a second light-shielding component 24. Along a direction perpendicular to a plane where the substrate 21 is located, the first light-shielding component 23 may at least partially overlap with the first active layer 22. Along a direction parallel to the plane where the substrate 21 is located, the second light-shielding component 24 may be located on a side of the first active layer 22.

The present disclosure provides the display panel 100. In one embodiment, the display panel 100 may include the substrate 21 and the first switch transistor 20 disposed on the side of the substrate 21 facing towards the light-emitting surface of the display panel 100. The first switch transistor 20 may be a driving transistor, or may be any other control switch transistor. The present disclosure may not specifically limit the function of the first switch transistor 20. The first switch transistor 20 may include the first active layer 22, a second gate 25, a first source 26 and a first drain 27. The second gate 25 may be disposed on the side of the first active layer 22 away from the substrate 21, or may be disposed on the side of the first active layer 22 facing towards the substrate 21, which may not be limited by the present disclosure. Either the first switch transistor 20 has a top-gate structure or a bottom-gate structure may be determined according to practical applications. FIG. 2 may merely illustrate an embodiment where the second gate 25 of the first switch transistor 20 is disposed on the side of the first active layer 22 facing towards the substrate 21.

Accordingly, in the disclosed display panel, the first light-shielding component 23 may be disposed on the side of the first active layer 22 of the first switch transistor 20 away from the substrate 21, and the first light-shielding component 23 may at least partially overlap with the first active layer 22. The second light-shielding component 24 may be disposed on at least part of the side of the first active layer 22, such that the first light-shielding component 23 and the second light-shielding component 24 may prevent light from being irradiated on the first active layer 22 from multiple directions. Therefore, the influence of illumination on the first switch transistor 20 may be reduced or even avoided, and the leakage current of the first switch transistor 20 may be reduced, which may facilitate to improve the display image quality of the display panel and to improve the display effect of the corresponding display device.

It should be noted that the present disclosure may not limit the area size of the first light-shielding component 23, as long as the first light-shielding component 23 is capable of preventing at least a portion of the light from being irradiated on the first active layer 22. In one embodiment, along the direction perpendicular to the plane where the substrate 21 is located, the first light-shielding component 23 may have a same area as the first active layer 22. As shown in FIG. 2, the first light-shielding component 23 may have an area greater than the first active layer 22. As shown in FIG. 3, the first light-shielding component 23 may have an area smaller than the first active layer 22.

It should be noted that the present disclosure may neither limit the area size of the second light-shielding component 24, nor limit the installation height of the second light-shielding component 24, as long as the second light-shielding component 24 is capable of preventing at least a portion of the light from being irradiated on the first active layer 22. In one embodiment, the second light-shielding component 24 may be located on a small portion of the side of the first active layer 22. In certain embodiments, the second light-shielding component 24 may be located on multiple sides of the first active layer 22.

The positional relationship between the first light-shielding component 23 and the second light-shielding component 24 may not be limited by the present disclosure. Along the direction perpendicular to the plane where the substrate 21 is located, the first light-shielding component 23 may partially overlap with the second light-shielding component 24. The positional relationship between the first light-shielding component 23 and the second light-shielding component 24 may be determined according to practical applications.

A plurality of insulating layers 31 may be disposed on a side of the substrate 21 of the display panel 100 facing towards the light-emitting surface of the display panel 100. Each structure in the first switch transistor 20, and the first light-shielding component 23 and the second light-shielding component 24 may be spaced apart by the insulating layer 31. The disposure of insulating layers 31 may avoid electrical signal crosstalk between components, and may ensure the normal use function of components such as transistors. The insulating layer 31 may include a buffer layer 318, a first sub-insulating layer 317, a first gate insulating layer 311, a second gate insulating layer 312, a first insulating layer 313, a second sub-insulating layer 314, a third sub-insulating layer 315 and a fourth sub-insulating layer 316. In addition, a light-emitting element 90 in the display panel 100 may be disposed on a side of the first light-shielding component 23 away from the substrate 21. The light-emitting element 90 may include an anode 91, a light-emitting layer 92, and a cathode 93 that are sequentially stacked along the direction perpendicular to the plane where the substrate 21 is located. Along the direction parallel to the plane where the substrate 21 is located, the region for disposing the light-emitting element 90 may be prepared by etching a portion of the pixel definition layer (PDL).

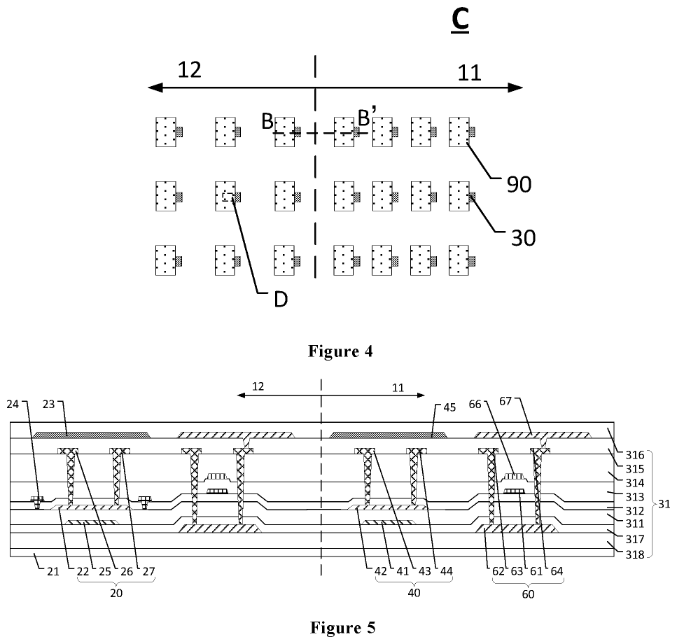

FIG. 4 illustrates a local zoom-in view of a region C of the display panel in FIG. 1 consistent with disclosed embodiments of the present disclosure. Referring to FIGS. 1-4, in one embodiment, the display panel 100 may include a plurality of pixel circuits 30.

The display panel 100 may include a first display region 11 and a second display region 12. A density of the pixel circuits 30 in the first display region 11 may be greater than a density of the pixel circuits 30 in the second display region 12. The first switch transistor 20 may be disposed in the pixel circuits 30 of the second display region 12.

In one embodiment, the display panel 100 may include the plurality of pixel circuits 30. The display panel 100 may further include the plurality of light-emitting elements 90. The pixel circuit 30 may be configured to be electrically connected with the light-emitting element 90 to transmit an electrical signal to the light-emitting element 90 to drive the light-emitting element 90 to emit light. FIG. 4 may merely illustrate the arrangement region of the pixel circuit 30 on a side of the light-emitting element 90 with a rectangular shape, which may not limit the specific structure of the pixel circuit 30.

The disclosed display panel 100 may include two display regions, the first display region 11 and the second display region 12. The density of the pixel circuits 30 in the first display region 11 may be different from the density of the pixel circuits 30 in the second display region 12. In one embodiment, the density of the pixel circuits 30 in the first display region 11 may be greater than the density of the pixel circuits 30 in the second display region 12. In view of this, the light transmittance of the second display region 12 may be greater than the light transmittance of the first display region 11. At least the first switch transistor 20 may be disposed in the pixel circuits 30 of the second display region 12, and the first switch transistor 20 in the second display region 12 may correspondingly be provided with the first light-shielding component 23 and the second light-shielding 24. Because the light transmittance of the second display region 12 is greater than the light transmittance of the first display region 11, the illumination of external light irradiated on the active layer of the transistor in the second display region 12 may have a greater influence on the display effect. Therefore, the disposure of the first switch transistor 20 having the first light-shielding component 23 and the second light-shielding component 24 block a portion of light in the second display region with a substantially small density of pixel circuits 30 may facilitate to effectively weaken the influence of external illumination on the transistor.

In other words, the display panel 100 may include the first display region 11 and the second display region 12, and the light transmittance of the second display region 12 may be greater than the light transmittance of the first display region 11. The first switch transistor 20 may be disposed in the second display region 12 with a substantially large light transmittance, and the first switch transistor 20 may be correspondingly provided with the first light-shielding component 23 and the second light-shielding component 24. Therefore, the disposure of the first light-shielding component 23 and the second light-shielding component 24 in the second display region 12 with a substantially large light transmittance in the display panel 100 may have a substantially obvious light-shielding effect on the corresponding first switch transistor 20, such that the second display region 12 of the display panel 100 may avoid the obviously poor display effect, which may facilitate to significantly improve the display effect of the corresponding display device.

Referring to FIG. 1 and FIG. 2, the second display region 12 may include an optical device region, and the first display region 11 may at least partially surround the optical device region.

In another embodiment, the second display region 12 may include the optical device region. For example, the second display region 12 may include a camera disposure region, or any other photosensitive device disposure region. The present disclosure may not limit the specific device provided in the second display region 12, which may be determined according to practical applications. Further, the first display region 11 may at least partially surround the optical device region. For example, the first display region 11 may be semi-enclosed around the optical device region, as shown in FIG. 1. Alternatively, the first display region 11 may be fully-enclosed around the optical device region, which may not be limited by the present disclosure. The specific arrangement of the first display region 11 and the second display region 12 may be determined according to practical applications.

Similarly, the second display region 12 may have greater light transmittance than the first display region 11. When the second display region 12 includes the first switch transistor 20, the first light-shielding component 23 and the second light-shielding component 24 may be disposed in the second display region 12, to shield the first active layer 22 of the corresponding first switch transistor 20. Therefore, the display panel 100 may avoid the obviously poor display effect, which may facilitate to significantly improve the display effect of the corresponding display device.

FIG. 5 illustrates a BB′-sectional view of the region C in FIG. 4 consistent with disclosed embodiments of the present disclosure. Referring to FIG. 1, FIG. 4 and FIG. 5, in one embodiment, the display panel 100 may include a second switch transistor 40 and a third light-shielding component 45. The second switch transistor 40 may be disposed on a side of the substrate 21 and in the pixel circuits 30 of the first display region 11. The second switch transistor 40 may include a second active layer 42. The third light-shielding component 45 may be disposed on a side of the second active layer 42 away from the substrate 21. Along a direction perpendicular to the plane where the substrate 21 is located, the third light-shielding component 45 may at least partially overlap with the second active layer 42.

In certain embodiments, in addition to the above-mentioned first switch transistor 20, the display panel 100 may further include the second switch transistor 40. The second switch transistor 40 may be disposed in the pixel circuits 30 of the first display region 11, and the second switch transistor 40 may be disposed on the side of the substrate 21 facing towards the light-emitting surface of the display panel 100. The second switch transistor 40 may include the second active layer 42, a second sub-gate 41, a second source 43 and a second drain 44. Referring to FIG. 5, the second sub-gate 41 may be disposed on the side of the second active layer 42 facing towards the substrate 21, which may not be limited by the present disclosure. In certain embodiments, the second sub-gate 41 may be disposed on the side of the second active layer 42 away from the substrate 21. Either the second switch transistor 40 has a top-gate structure or a bottom-gate structure may be determined according to practical applications.

Further, the display panel 100 may include the third light-shielding component 45. The third light-shielding component 45 may be disposed on the side of the second active layer 42 away from the substrate 21. Along the direction perpendicular to the plane where the substrate 21 is located, the third light-shielding component 45 may at least partially overlap with the second active layer 42. In view of this, when the external light is irradiated toward the inner side of the display panel 100 along the light-emitting surface side of the display panel 100, the third light-shielding component 45 may be configured to prevent a portion of the light from being irradiated on the second active layer 42, thereby reducing the amount of light irradiated on the second active layer 42, weakening the influence of illumination on the second switch transistor 40, and reducing the leakage current of the second switch transistor 40. Therefore, the display image quality of the first display region 11 in the display panel 100 may be improved, and the display effect of the corresponding display device may be improved.

It should be noted that when the display panel 100 includes the first display region 11 and the second display region 12, and the density of the pixel circuits 30 in the second display region 12 is smaller than the density of the pixel circuits 30 in the first display region 11, the light transmittance of the second display region 12 may be greater than the light transmittance of the first display region 11. Therefore, when external light irradiates on the display panel 100, the influence on the second display region 12 may be greater than the influence on the first display region 11 in the display panel 100. The first light-shielding component 23 and the second light-shielding component 24 may be disposed in the second display region 12 to together reduce the amount of light irradiated on the first active layer 22, and the third light-shielding component 45 may be disposed in the first display region 11 to reduce the amount of light irradiated on the second active layer 42. In view of this, the disposure of the first light-shielding component 23, the second light-shielding component 24, and the third light-shielding component 45 at the same time may reduce the amount of light irradiated on the active layers (the first active layer 22 and the second active layer 42) of the transistors in the display panel 100, and may reduce the leakage currents of the first switch transistor 20 and the second switch transistor 40, thereby improving the display image quality of the display panel 100 and improving the display effect of the corresponding display device.

Referring to FIG. 1, FIG. 4 and FIG. 5, in one embodiment, the third light-shielding component 45 and the first light-shielding component 23 may be disposed on a same layer.

In certain embodiments, the display panel 100 may include the first display region 11 and the second display region 12. The third light-shielding component 45 may be disposed in the first display region 11, and the first light-shielding component 23 may be disposed in the second display region 12. The third light-shielding component 45 may be configured to prevent a portion of the external light from being irradiated on the second active layer 42 of the second switch transistor 40, and the first light-shielding component 23 may be configured to prevent a portion of the external light from being irradiated on the first active layer 22 of the first switch transistor 20. Therefore, the third light-shielding component 45 and the first light-shielding component 23 may be disposed on the same film layer structure of the display panel 100. In view of this, the third light-shielding component 45 and the first light-shielding component 23 may be manufactured through a same process in the manufacturing process of the display panel 100, to avoid the excessive increase of the manufacturing processes of the display panel 100 due to the addition of the first light-shielding component 23 and the third light-shielding component 45, and to avoid the increase of the overall film thickness of the display panel 100 due to the disposure of the first light-shielding component 23 and the third light-shielding component 45. Therefore, the overall production processes of the display panel 100 may be saved, and at the same time, the required number of mask plates in the manufacturing process of the display panel 100 may be reduced, thereby reducing the manufacturing cost of the display panel 100.

In one embodiment, the first light-shielding component 23 and the third light-shielding component 45 may be disposed on the same layer of the display panel 100, which may not be limited by the present disclosure. When the number of film layers of the display panel 100 allows, the first light-shielding component 23 and the third light-shielding component 45 may be disposed on different layers.

Referring to FIG. 1, FIG. 4 and FIG. 5, in one embodiment, the first active layer 22 and the second active layer 42 may be disposed on a same layer. Both the first active layer 22 and the second active layer 42 may include metal oxide semiconductor layers.

In one embodiment, when the display panel 100 includes the first display region 11 and the second display region 12, the first display region 11 includes the first active layer 22 corresponding to the first switch transistor 20, and the second display region 12 includes the second active layer 42 corresponding to the second switch transistor 40. The first active layer 22 and the second active layer 42 may be disposed on a same layer structure of the display panel 100. In view of this, the first active layer 22 and the second active layer 42 may be made through a same manufacturing process during the manufacturing process of the display panel 100, to avoid the excessive increase of the manufacturing processes of the display panel 100 and the increase of the overall film thickness of the display panel 100 due to the disposure of the first active layer 22 and the second active layer 42. Therefore, the overall production processes of the display panel 100 may be saved, and at the same time, the required number of mask plates in the manufacturing process of the display panel 100 may be reduced, thereby reducing the manufacturing cost of the display panel 100.

In one embodiment, the first active layer 22 and the second active layer 42 may be disposed on the same layer of the display panel 100, which may not be limited by the present disclosure. When the number of film layers of the display panel 100 allows, the first active layer 22 and the second active layer 42 may be disposed on different layers.

It should be noted that the first active layer 22 and the second active layer 42 in the display panel 100 may be configured as metal oxide semiconductor layers, and the metal oxide semiconductor layers as the active layers (the first active layer 22 and the second active layer 42) of the transistors may avoid the leakage current problem of the transistor, thereby further avoiding the poor display effect due to the abnormal problem of the transistors (the first switch transistor 20 and the second switch transistor 40) during use, and improving the display effect of the display panel 100.

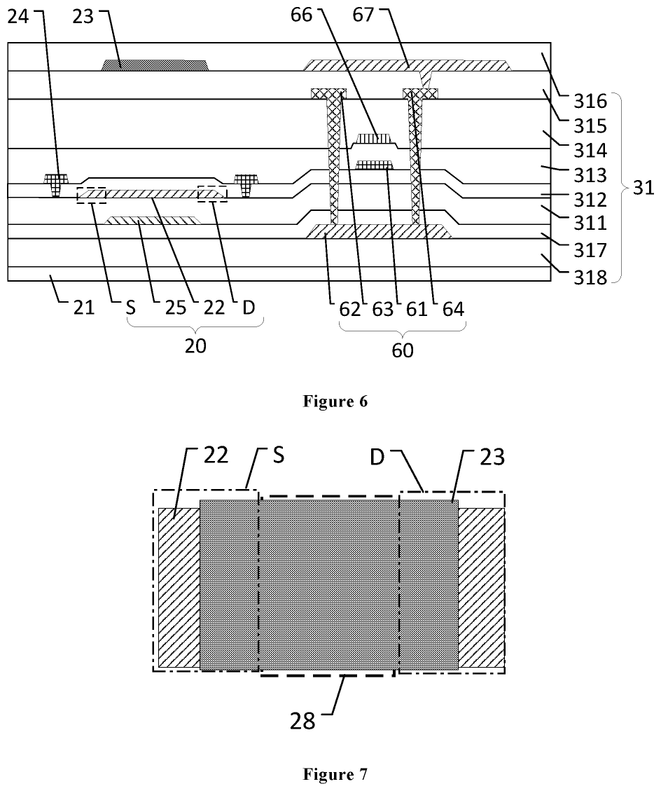

FIG. 6 illustrates another AA′-sectional view of the display panel in FIG. 1 consistent with disclosed embodiments of the present disclosure, and FIG. 7 illustrates a perspective view of a region D in FIG. 4 consistent with disclosed embodiments of the present disclosure. Referring to FIG. 1 and FIGS. 4-7, in one embodiment, the first active layer 22 may include a source, a drain, and a conductive channel 28 between the source and the drain of the first switch transistor 20.

Along the direction perpendicular to the plane where the substrate 21 is located, the first light-shielding component 23 may overlap with the conductive channel 28 of the first switch transistor 20.

In one embodiment, referring to FIG. 6, the first active layer 22 may include the source S, the drain D and the conductive channel 28 between the source S and the drain D of the corresponding first switch transistor 20. In other words, the source S and the drain D in the first switch transistor 20 may be formed in the same layer as the first active layer 22 (the metal source and drain may not be additionally formed). The conductive channel 28 may include a region where the first active layer 22 overlaps with the second gate 25 in a direction perpendicular to the plane where the substrate 21 is located. In view of this, along the direction perpendicular to the plane where the substrate 21 is located, the first light-shielding component 23 may at least overlap with the conductive channel 28 of the first switch transistor 20, or the first light-shielding component 23 may at least partially overlap with the conductive channel 28 of the first switch transistor 20. Referring to FIG. 7, the first light-shielding component 23 may fully overlap with the conductive channel 28 of the first switch transistor 20, which may not be limited by the present disclosure. The area of the overlapped region between the first light-shielding component 23 and the conductive channel 28 of the first switch transistor 20 may be determined according to practical applications.

The leakage current problem caused by the external light irradiating on the first active layer 22 may be mainly due to the light illumination on the conductive channel 28 of the first active layer 22. Therefore, the first light-shielding component 23 may at least prevent a portion of the light from being irradiated on the conductive channel 28 of the first switch transistor 20, which may weaken the influence of the illumination on the transistor, may reduce the leakage current of the transistor, and may further improve the display effect of the display panel 100.

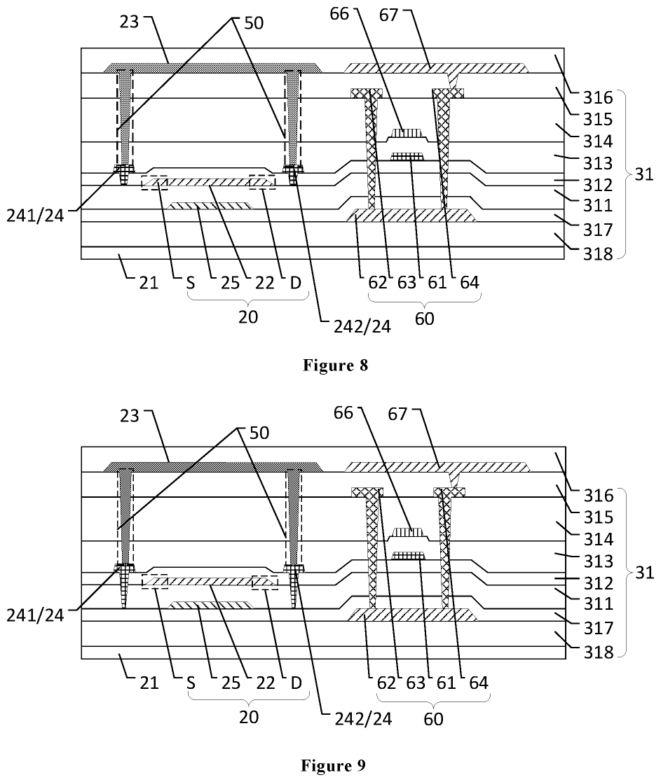

FIG. 8 illustrates another AA′-sectional view of the display panel in FIG. 1 consistent with disclosed embodiments of the present disclosure. In one embodiment, referring to FIG. 1 and FIG. 8, the first light-shielding component 23 and the second light-shielding component 24 may be connected with each other through a first via 50.

In one embodiment, the display panel 100 may be simultaneously provided with the first light-shielding component 23 and the second light-shielding component 24, to prevent the light from being irradiated on the first active layer 22. The first light-shielding component 23 and the second light-shielding component 24 may be connected with each other through the first via 50, such that the first light-shielding component 23 and the second light-shielding component 24 may be connected as an integral structure, which may improve the light blocking area and light blocking effect of the first light-shielding component 23 and the second light-shielding component 24, and may further reduce the amount of light irradiated on the first active layer 22 from a space between the second light-shielding component 24 and the first light-shielding component 23.

Referring to FIG. 1, FIG. 4, FIG. 7 and FIG. 8, the first active layer 22 may include the source S, the drain D, and the conductive channel 28 between the source S and the drain D of the first switch transistor 20. The second light-shielding component 24 may include a first sub-light-shielding component 241 disposed on a side of the source S away from the drain D, and a second sub-light-shielding component 242 disposed on a side of the drain D away from the source S.

In one embodiment, the first active layer 22 may include the conductive channel 28. Specifically, the first active layer 22 may include the source S, the drain D, and the conductive channel 28 between the source S and the drain D of the first switch transistor 20. In view of this, the second light-shielding component 24 may include the first sub-light-shielding component 241 disposed on the side of the source S away from the drain D. The first sub-light-shielding component 241 may be configured to block the light irradiated on the first active layer 22 from the side of the source S far away from the drain D. The second light-shielding component 24 may also include the second sub-light-shielding component 242 disposed on the side of the drain D away from the source S. The second sub-light-shielding component 242 may be configured to block the light irradiated on the first active layer 22 from the side of the drain D far away from the source S. In other words, the second light-shielding component 24 may include the first sub-light-shielding component 241 and the second sub-light-shielding component 242, and the first sub-light-shielding component 241 and the second sub-light-shielding component 242 may be configured to block the light irradiated on the first active layer 22 from the sides of the source S and the drain D, which may reduce the influence of illumination on the transistor (the first switch transistor 20), and may reduce the leakage current of the transistor, thereby improving the display effect of the display panel 100.

Referring to FIG. 1, FIG. 4, FIG. 7 and FIG. 8, in one embodiment, the first sub-light-shielding component 241 may be connected to the first light-shielding component 23 through the first via 50, and the second sub-light-shielding component 242 may be connected to the first light-shielding component 23 through another first via 50.

In one embodiment, when the display panel 100 is simultaneously provided with the first light-shielding component 23 and the second light-shielding component 24 to prevent the light from being irradiated on the first active layer 22, the second light-shielding component 24 may include the first sub-light-shielding component 241 and the second sub-light-shielding component 242 on the sides of the source and drain. In view of this, a side of the first light-shielding component 23 may be connected to the first sub-light-shielding component 241 through the first via 50, and the other side of the first light-shielding component 23 may be connected to the second sub-light-shielding component 242 through another first via 50. Therefore, the first light-shielding component 23 and the second light-shielding component 24 including the first sub-light-shielding component 241 and the second sub-light-shielding component 242 may be connected as an integral structure. The first light-shielding component 23 and the second light-shielding component 24 may form a semi-closed structure, which may improve the blocking effect of the first light-shielding component 23 and the second light-shielding component 24 on light, may further reduce the amount of light irradiated on the first active layer 22 from a space between the second light-shielding component 24 and the first light-shielding component 23, and may facilitate to improve the effect of reducing the leakage current of the transistor.

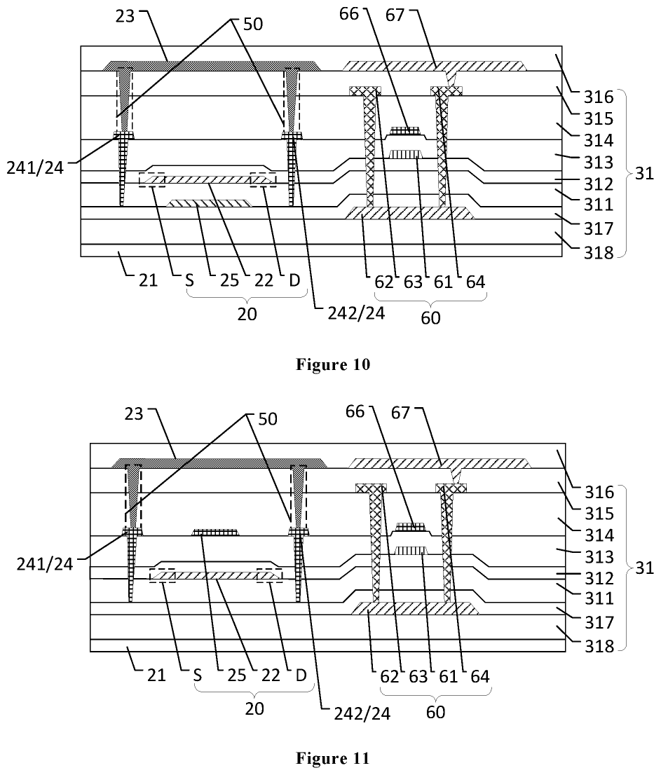

FIG. 9 illustrates another AA′-sectional view of the display panel in FIG. 1 consistent with disclosed embodiments of the present disclosure, and FIG. 10 illustrates another AA′-sectional view of the display panel in FIG. 1 consistent with disclosed embodiments of the present disclosure. Referring to FIG. 1, FIG. 4, and FIGS. 7-10, the display panel 100 may include the first gate insulating layer 311, the second gate insulating layer 312, and the first insulating layer 313. The first gate insulating layer 311 may be disposed on the side of the first insulating layer 313 facing towards the substrate 21, the second gate insulating layer 312 may be disposed between the first gate insulating layer 311 and the first insulating layer 313, and the first active layer 22 may be formed between the first gate insulating layer 311 and the second gate insulating layer 312.

The second light-shielding component 24 may penetrate through at least one of the first gate insulating layer 311, the second gate insulating layer 312 and the first insulating layer 313.

In one embodiment, the display panel 100 may include the first gate insulating layer 311, the second gate insulating layer 312, and the first insulating layer 313 disposed on a side of the substrate 21. Along the direction perpendicular to the plane where the substrate 21 is located, the first gate insulating layer 311, the second gate insulating layer 312, and the first insulating layer 313 may be sequentially stacked over the side of the substrate 21 facing towards the light-emitting surface of the display panel 100. The first active layer 22 may be formed between the first gate insulating layer 311 and the second gate insulating layer 312.

In view of this, the second light-shielding component 24 may be formed by penetrating through at least one of the first gate insulating layer 311, the second gate insulating layer 312 and the first insulating layer 313. In one embodiment, the second light-shielding component 24 may be formed by penetrating through the first gate insulating layer 311. In another embodiment, referring to FIG. 8, the second light-shielding component 24 may be formed by merely penetrating through the second gate insulating layer 312. In certain embodiments, the second light-shielding component 24 may be formed by merely penetrating through the first insulating layer 313, or the second light-shielding component 24 may be formed by penetrating through the first gate insulating layer 311 and the second gate insulating layer 312. Referring to FIG. 9, the second light-shielding component 24 may be formed by penetrating through the second gate insulating layer 312 and the first insulating layer 313. Referring to FIG. 10, the second light-shielding component 24 may be formed by penetrating through the first gate insulating layer 311, the second gate insulating layer 312 and the first insulating layer 313.

In addition, the second light-shielding component 24 may include a segmented two-section structure. One section of the second light-shielding component 24 may be formed by penetrating through the first gate insulating layer 311, and the other section of the second light-shielding component 24 may be formed by penetrating through the first insulating layer 313. It should be noted that the above-mentioned disposure methods of the second light-shielding components 24 may merely be used as examples, which may not be limited by the present disclosure. The disposure method of the second light-shielding component 24 may be determined according to practical applications.

In one embodiment, the second light-shielding component 24 may be formed by penetrating through at least one of the first gate insulating layer 311, the second gate insulating layer 312, and the first insulating layer 313. Therefore, in the direction perpendicular to the plane where the substrate 21 is located, the second light-shielding component 24 with a certain height may block a portion of the light emitted from the side of the first active layer 22 and irradiated on the first active layer 22. The second light-shielding component 24 and the first light-shielding component 23 may cooperate with each other to reduce the amount of light irradiated on the first active layer 22 from the side of the second light-shielding component 24 and the first light-shielding component 23 away from the first active layer 22, to further prevent more light from being irradiated on the first active layer 22, and to reduce the leakage current of the first switch transistor 20, thereby improving the display effect of the display panel 100.

It should be noted that, if conditions permit, the more layers of the insulating layer 31 that the second light-shielding component 24 penetrates, the higher the height of the second light-shielding component 24 along the direction perpendicular to the plane where the substrate 21 is located, and the more the amount of light that is prevented by the second light-shielding component 24 from being irradiated on the first active layer 22, which may effectively improve the image display effect of the display panel 100.

It should be noted that in the embodiments associated with FIGS. 8-10, the first light-shielding component 23 may be connected to the second light-shielding component 24 through the first via 50, which may not be limited by the present disclosure. In certain embodiments, the first via 50 may not be provided between the first light-shielding component 23 and the second light-shielding component 24, whether to provide the first via 50 may be determined according to practical applications.

It should be noted that in the embodiments associated with FIGS. 8-10, a planar structure portion of the second light-shielding component 24 may be located in the first insulating layer 313. In another embodiment, the planar structure portion of the second light-shielding component 24 may be disposed in any other insulating layer 31 on the side of the first insulating layer 313 facing towards the first light-shielding component 23, which may not be limited by the present disclosure. The disposure of the planar structure portion of the second light-shielding component 24 may be determined according to practical applications.

Referring to FIG. 1, FIG. 4, FIG. 7, FIG. 8 and FIG. 10, the display panel 100 may further include a plurality of driving transistors 60 disposed on a side of the substrate 21, and a capacitive metal layer 66 disposed on a side of the driving transistor 60 away from the substrate 21. The driving transistor 60 may include a third active layer 62 and a first gate 61 disposed on the side of the third active layer 62 away from the substrate 21.

The second light-shielding component 24 may be disposed on a same layer as the first gate 61 or the capacitive metal layer 66.

In one embodiment, the display panel 100 may further include the plurality of driving transistors 60 and the capacitive metal layer 66. The driving transistors 60 may be disposed on the side of the substrate 21 facing towards the light-emitting surface of the display panel 100, and the capacitive metal layer 66 may be disposed on the side of the first gate 61 of the driving transistor 60 away from the substrate 21. The driving transistor 60 may include the third active layer 62, the first gate 61, a third source 63 and a third drain 64. The first gate 61 may be disposed on the side of the third active layer 62 away from the substrate 21, which may not be limited by the present disclosure. In another embodiment, the first gate 61 may be disposed on the side of the third active layer 62 facing towards the substrate 21. Either the driving transistor 60 has a top-gate structure or a bottom-gate structure may be determined according to practical applications. In one embodiment, the third source 63 and the third drain 64 of the driving transistor 60 may be disposed on the same layer as the third active layer 62. In other words, additional metal source or drain may not be provided, and the semiconducting third active layer may be used to form the third source 63 and the third drain 64.

In one embodiment, the third active layer 62 may include a low temperature polysilicon layer.

Based on the above structure, the driving transistor 60 and the capacitive metal layer 66 may be disposed on the side of the substrate 21, and the driving transistor 60 may include the third active layer 62 and the first gate 61 disposed on the side of the third active layer 62 away from the substrate 21. In one embodiment, referring to FIG. 8, the second light-shielding component 24 may be disposed on the same layer as the first gate 61. In another embodiment, referring to FIG. 10, the second light-shielding component 24 may be disposed on the same layer as the capacitive metal layer 66. In view of this, the number of film layers required for disposing the second light-shielding component 24, the first gate 61, and the capacitive metal layer 66 in the display panel 100 may be reduced as much as possible, which may avoid the increase of the manufacturing processes of the display panel 100 caused by disposing such structures in the display panel 100, may avoid the increase of the overall thickness of the display panel 100, and may maintain the thin design requirements of the display panel 100 and improve user experience on the basis of ensuring and improving the display function and display effect of the display panel 100.

FIG. 11 illustrates another AA′-sectional view of the display panel in FIG. 1 consistent with disclosed embodiments of the present disclosure. Referring to FIG. 1, FIG. 4, FIG. 7 and FIG. 11, in one embodiment, the display panel 100 may include the plurality of driving transistors 60 disposed on the side of the substrate 21, and the capacitive metal layer 66 disposed on the side of the driving transistor 60 away from the substrate 21. The first switch transistor 20 may include a second gate 25 disposed on the side of the first active layer 22 away from the substrate 21. The second gate 25 may be disposed on the same layer as the capacitor metal layer 66.

In one embodiment, the display panel 100 may further include the plurality of driving transistors 60 and the capacitive metal layer 66. The driving transistor 60 may be disposed the side of the substrate 21 facing towards the light-emitting surface of the display panel 100. The capacitive metal layer 66 may be disposed on the side of the first gate 61 of the driving transistor 60 away from the substrate 21. In view of this, the first switch transistor 20 may include the first active layer 22, the second gate 25, the source S and the drain D. The second gate 25 may be disposed on the side of the first active layer 22 away from the substrate 21.

Based on the above structure, when the driving transistor 60 and the capacitive metal layer 66 are disposed on the side of the substrate 21, and the second gate 25 of the first switch transistor 20 is disposed on the side of the first active layer 22 away from the substrate 21, in one embodiment, the second gate 25 may be disposed on the same layer as the capacitor metal layer 66. In view of this, the number of film layers required for disposing the second gate 25 and the capacitive metal layer 66 in the display panel 100 may be reduced as much as possible, which may avoid the increase of the manufacturing processes of the display panel 100 caused by disposing such structures in the display panel 100, may avoid the increase of the overall thickness of the display panel 100, and may maintain the thin design requirements of the display panel 100 and improve user experience on the basis of ensuring and improving the display function and display effect of the display panel 100.

Referring to FIG. 1, FIG. 4, and FIGS. 7-11, the display panel 100 may further include the plurality of driving transistors 60 disposed on the side of the substrate 21, and the driving transistor 60 may include the source and the drain. The display panel 100 may also include a conductive layer 67 disposed on the side of the driving transistor 60 away from the substrate 21. The conductive layer 67 may be electrically connected to the source or the drain of the driving transistor 60.

The first light-shielding component 23 may be disposed on a same layer as the conductive layer 67.

In one embodiment, the display panel 100 may further include the plurality of driving transistors 60. The driving transistors 60 may be disposed on the side of the substrate 21 facing towards the light-emitting surface of the display panel 100. In view of this, the driving transistor 60 may include the third active layer 62, the first gate 61, the source and the drain. The source and the drain herein may refer to the third source 63 and the third drain 64. The first gate 61 may be disposed on the side of the third active layer 62 away from the substrate 21, which may not be limited by the present disclosure. In another embodiment, the first gate 61 may be disposed on the side of the third active layer 62 facing towards the substrate 21. Either the driving transistor 60 has a top-gate structure or a bottom-gate structure may be determined according to practical applications.

In view of this, the display panel 100 may further include the conductive layer 67, and the conductive layer 67 may be disposed on the side of the driving transistor 60 away from the substrate 21. The conductive layer 67 may be electrically connected to the third source 63 or the third drain 64 of the driving transistor 60, to achieve the electrical connection relationship between the conductive layer 67 and the driving transistor 60, thereby realizing the electrical signal transmission function of the conductive layer 67 in the display panel 100. The light-shielding component 23 may be disposed on the same layer as the conductive layer 67. In view of this, the first light-shielding component 23 and the conductive layer 67 may be made through a same manufacturing process during the manufacturing process of the display panel 100, to avoid the increase of the manufacturing processes of the display panel 100 due to the disposure of the first light-shielding component 23 and the conductive layer 67, and to avoid the increase of the number of film layers of the display panel 100. Therefore, the overall production processes of the display panel 100 may be saved, and at the same time, the required number of mask plates in the manufacturing process of the display panel 100 may be reduced, thereby reducing the manufacturing cost of the display panel 100.

Referring to FIG. 2, the cross-sectional view of the display panel 100 shown in FIG. 2 may include the conductive layer 67 and an anode 91 of the light-emitting element 90, which may not be limited by the present disclosure. For example, the anode 91 of the light-emitting element 90 may be directly electrically connected to the driving transistor 60. In other words, the conductive layer 67 may be directly multiplexed as the anode 91 of the light-emitting element 90, which may reduce the manufacturing process of the display panel 100, and may improve the production efficiency of the display panel 100.

It should be noted that the present disclosure may not illustrate any other structural component disposed on the side of the first light-shielding component 23 away from the substrate 21, and the any other structural component disposed on the side of the first light-shielding component 23 away from the substrate 21 may be determined according to practical applications.

Referring to FIG. 1 and FIG. 2, the light absorptivity of the second light-shielding component 24 may be greater than the light absorptivity of the first light-shielding component 23.

In one embodiment, the first light-shielding component 23 and the second light-shielding component 24 may be simultaneously disposed on the corresponding first switch transistor 20 of the display panel 100. The first light-shielding component 23 and the second light-shielding component 24 may not only prevent the light from being irradiated on the first switch transistor, but also have the function of absorbing light, to prevent the blocked light from being reflected to any other direction. In view of such disposure, the light absorptivity of the second light-shielding component 24 may be greater than the light absorptivity of the first light-shielding component 23, to improve the blocking effect of the second light-shielding component 24 on the side light irradiated on the first active layer 22.

It should be noted that the first light-shielding component 23 may be mainly configured to block the light that is vertically incident on the first active layer 22 from the light-emitting surface side of the display panel 100. Even if the light absorptivity of the first light-shielding component 23 is poor, when more external light is irradiated on the surface of the first light-shielding component 23, the first light-shielding component 23 may reflect the light toward the outside of the display panel 100, and may not affect the display effect of the display panel 100. However, the second light-shielding component 24 may be mainly configured to block the light that is incident on the side of the first active layer 22 from the side of the first active layer 22. If the light absorptivity of the second light-shielding component 24 is substantially poor, lots of light may be reflected by the second light-shielding component 24 when being irradiated on the surface of the second light-shielding component 24, and a portion of the light reflected by the second light-shielding component 24 may be reflected towards the first active layer 22 by certain structural components in the display panel 100, which may still be likely to increase the corresponding leakage current of the first active layer 22. Therefore, the second light-shielding component 24 may be set to have a substantially high light absorptivity, which may further reduce the amount of light irradiated on the side of the first active layer 22, may effective reduce the influence of illumination on the transistor (the first switch transistor 20), and may facilitate to improve the display effect of the display panel 100.

It should be noted that the first light-shielding component 23 and the second light-shielding component 24 may be made of an organic material or an inorganic material. The organic material may at least include light-absorbing resin, and the inorganic material may include at least one of titanium, chromium, aluminum, molybdenum and composite metal oxide.

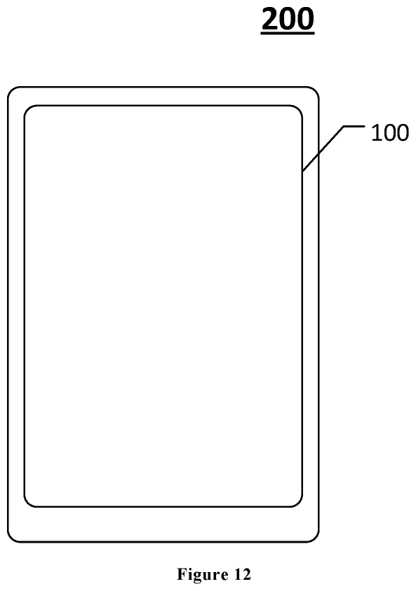

The present disclosure also provides a display device. FIG. 12 illustrates a schematic diagram of a display device consistent with disclosed embodiments of the present disclosure. Referring to FIG. 12 and in conjunction with FIGS. 1-11, a display device 200 may include a display panel 100. The display panel 100 may include a display panel 100 in any one of the disclosed embodiments.

It should be noted that the embodiments of the display device 200 in the present disclosure may refer to the above-disclosed embodiments of the display panel 100, which may not be repeated herein. The display device 200 may include any product and component with a touch-control function, such as a mobile phone, a tablet computer, a television, a touch controller, a notebook computer, a navigator, etc.

The disclosed display panel and display device may have following beneficial effects. In the disclosed display panel and display device, the first light-shielding component may be disposed on the side of the first active layer of the first switch transistor away from the substrate in the display panel, and the first light-shielding component may at least partially overlap with the first active layer. The second light-shielding component may be disposed on at least part of the side of the first active layer. Therefore, the first light-shielding component and the second light-shielding component may prevent a portion of the light from being irradiated on the first active layer, to weaken or even avoid the influence of illumination on the transistor, and to reduce the leakage current of the transistor, thereby improving the display image quality of the display panel and improving the display effect of the corresponding display device.

The description of the disclosed embodiments is provided to illustrate the present disclosure to those skilled in the art. Various modifications to these embodiments will be readily apparent to those skilled in the art, and the generic principles defined herein may be applied to other embodiments without departing from the spirit or scope of the disclosure. Thus, the present disclosure is not intended to be limited to the embodiments illustrated herein but is to be accorded the widest scope consistent with the principles and novel features disclosed herein.

What is claimed is:

1. A display panel, comprising:
a substrate;
a first switch transistor, disposed on a side of the substrate, wherein the first switch transistor includes a first active layer;
a first light-shielding component, disposed on a side of the first active layer away from the substrate, wherein along a direction perpendicular to a plane where the substrate is located, the first light-shielding component at least partially overlaps with the first active layer; and
a second light-shielding component, wherein along a direction parallel to the plane where the substrate is located, the second light-shielding component is disposed on a side of the first active layer.

2. The display panel according to claim 1, further including:
a plurality of pixel circuits; and
a first display region and a second display region, wherein:
a density of the pixel circuits in the first display region is greater than a density of the pixel circuits in the second display region, and
the first switch transistor is disposed in the pixel circuits in the second display region.

3. The display panel according to claim 2, wherein:
the second display region includes an optical device region, and
the first display region at least partially surrounds the optical device region.

4. The display panel according to claim 2, further including:
a second switch transistor, disposed on a side of the substrate and in the pixel circuits in the first display region, wherein the second switch transistor includes a second active layer; and
a third light-shielding component, disposed on a side of the second active layer away from the substrate, wherein along the direction perpendicular to the plane where the substrate is located, the third light-shielding component at least partially overlaps with the second active layer.

5. The display panel according to claim 4, wherein:
the third light-shielding component is disposed on a same layer as the first light-shielding component.

6. The display panel according to claim 4, wherein:
the first active layer is disposed on a same layer as the second active layer, and
each of the first active layer and the second active layer includes a metal oxide semiconductor layer.

7. The display panel according to claim 1, wherein:
the first active layer includes a source and a drain of the first switch transistor, and a conductive channel between the source and the drain, wherein along the direction perpendicular to the plane where the substrate is located, the first light-shielding component overlaps with the conductive channel of the first switch transistor.

8. The display panel according to claim 1, wherein:
the first light-shielding component and the second light-shielding component are connected with each other through one or more first vias.

9. The display panel according to claim 8, wherein:
the first active layer includes a source and a drain of the first switch transistor, and a conductive channel between the source and the drain, and
the second light-shielding component includes a first sub-light-shielding component disposed on a side of the source away from the drain, and a second sub-light-shielding component disposed on a side of the drain away from the source.

10. The display panel according to claim 9, wherein:
the first sub-light-shielding component is connected to the first light-shielding component through a first via of the one or more first vias, and the second sub-light-shielding component is connected to the first light-shielding component through another first via of the one or more first vias.

11. The display panel according to claim 1, further including:
a first gate insulating layer, a second gate insulating layer, and a first insulating layer sequentially disposed over a side of the first active layer facing towards the first light-shielding component, wherein:
the first gate insulating layer is disposed over a side of the first insulating layer facing towards the substrate, the second gate insulating layer is disposed between the first gate insulating layer and the first insulating layer, and the first active layer is formed between the first gate insulating layer and the second gate insulating layer, and
the second light-shielding component penetrates through at least one of the first gate insulating layer, the second gate insulating layer and the first insulating layer.

12. The display panel according to claim 1, further including:
a plurality of driving transistors disposed on a side of the substrate, and a capacitive metal layer disposed on a side of a driving transistor of the plurality of driving transistors away from the substrate, wherein:
the driving transistor includes a third active layer and a first gate disposed on a side of the third active layer away from the substrate, and
the second light-shielding component is disposed on a same layer as one of the first gate and the capacitive metal layer.

13. The display panel according to claim 1, further including:
a plurality of driving transistors disposed on a side of the substrate, and a capacitive metal layer disposed on a side of a driving transistor of the plurality of driving transistors away from the substrate, wherein:
the first switch transistor further includes a second gate disposed on a side of the first active layer away from the substrate, and
the second gate is disposed on a same layer as the capacitor metal layer.

14. The display panel according to claim 1, further including:
a plurality of driving transistors disposed on a side of the substrate, wherein a driving transistor of the plurality of driving transistors includes a source and a drain; and
a conductive layer disposed on a side of the driving transistor away from the substrate, wherein the conductive layer is electrically connected to one of the source and the drain of the driving transistor, and the first light-shielding component is disposed on a same layer as the conductive layer.

15. The display panel according to claim 1, wherein:
a light absorptivity of the second light-shielding component is greater than a light absorptivity of the first light-shielding component.

16. A display device, comprising:
a display panel, the display panel including:
a substrate;
a first switch transistor, disposed on a side of the substrate, wherein the first switch transistor includes a first active layer;
a first light-shielding component, disposed on a side of the first active layer away from the substrate, wherein along a direction perpendicular to a plane where the substrate is located, the first light-shielding component at least partially overlaps with the first active layer; and
a second light-shielding component, wherein along a direction parallel to the plane where the substrate is located, the second light-shielding component is disposed on a side of the first active layer.
